(19) United States
(12) Patent Application Publication
(10) Pub. No.: US 2026/0191114 A1
(43) Pub. Date: Jul. 2, 2026

(54) SEMICONDUCTOR STRUCTURE AND METHOD FOR FABRICATING SAME

(71) Applicant: WUHAN XINXIN SEMICONDUCTOR MANUFACTURING CO., LTD., Wuhan (CN)

(72) Inventors: Peng ZHU, Wuhan (CN); Zilu YE, Wuhan (CN); Beibei SHENG, Wuhan (CN); Sheng HU, Wuhan (CN)

(21) Appl. No.: 19/416,820

(22) Filed: Dec. 11, 2025

(30) Foreign Application Priority Data
Jan. 2, 2025 (CN) 202510005371.7

(51) Int. Cl. H10W 90/20; H10W 80/00; H10W 90/00

(52) U.S. Cl. CPC H10W 90/288; H10W 80/314; H10W 90/297; H10W 90/792

(57) ABSTRACT

A semiconductor structure and a method for fabricating it are disclosed. In the semiconductor structure, a heat-equalizing layer is arranged between stacked first and second substrates and includes a heat-dissipating material film, which can promote horizontal transfer of heat produced in the semiconductor structure between the first and second substrates.

### CROSS-REFERENCE TO RELATED APPLICATION

This application claims the priority of Chinese patent application number 202510005371.7, filed on Jan. 2, 2025, and entitled “SEMICONDUCTOR STRUCTURE AND METHOD FOR FABRICATING SAME”, the entire contents of which are incorporated herein by reference.

### TECHNICAL FIELD

The present invention relates to the field of semiconductor technology and, in particular, to a semiconductor structure and a method for fabricating it.

### BACKGROUND

Three-dimensional (3D) integration is a technique capable of fabricating a high-performance chip with integrated circuits, which are interconnected. As various techniques and applications emerge and develop, increasingly demanding requirements are being placed on chips, motivating the development and application of 3D integration techniques to higher levels gradually towards a vision where various constituent components are seen from a system point of view, to achieve higher overall performance.

As 3D integration technology develops to higher levels, vertically stacked chips are increasingly decreasing in thickness. However, thinner semiconductor layers (e.g., silicon layers) in such chips will weaken temperature equalization, leading to heat concentration, which are detrimental to their stability and performance.

### SUMMARY OF THE INVENTION

The present invention provides a semiconductor structure with improved stability and performance because of mitigated heat concentration and a method for fabricating such a semiconductor structure.

In one aspect, the present invention provides a semiconductor structure comprising:
a first substrate comprising at least one first metal interconnect;
a second substrate stacked on the first substrate and comprising at least one second metal interconnect;
a heat-equalizing layer that is sandwiched between the first and second substrates and comprises a heat-dissipating material film; and
at least one third metal interconnect extending through at least the heat-equalizing layer and electrically connecting the first metal interconnect to the second metal interconnect.

Optionally, the heat-dissipating material film may comprise one of diamond, hexagonal boron nitride (h-BN) and carbon nanotubes, or a combination of two or more thereof.

Optionally, the heat-equalizing layer may comprise at least one heat-dissipating metal block extending through the heat-dissipating material film.

Optionally, the heat-equalizing layer may comprise at least one heat-dissipating groove, wherein the heat-dissipating groove extends parallel to the first substrate from an edge of the heat-equalizing layer into the heat-equalizing layer.

Optionally, the first substrate may comprise a base substrate having a front side and a backside opposite to the front side, wherein the first metal interconnect comprises a front-side metal interconnect layer formed on the front side of the base substrate and at least one through silicon via (TSV) extending through the base substrate from the backside thereof and connected to the front-side metal interconnect layer, and wherein the third metal interconnect comprises a metal interconnect block that extends through the heat-equalizing layer and is connected to the TSV.

Optionally, the first substrate may comprise a base substrate having a front side and a backside opposite to the front side, wherein the first metal interconnect comprises a front-side metal interconnect layer formed on the front side of the base substrate, and wherein the third metal interconnect comprises at least one TSV that extends through the heat-equalizing layer and the base substrate and is connected to the front-side metal interconnect layer.

In another aspect, the present invention provides a method for fabricating a semiconductor structure, which comprises:
providing a first substrate comprising at least one first metal interconnect;
forming a heat-equalizing layer that comprises a heat-dissipating material film on a surface of the first substrate;
forming at least one third metal interconnect extending through at least the heat-equalizing layer and electrically connected to the first metal interconnect; and
stacking a second substrate on a side of the heat-equalizing layer away from the first substrate, wherein the second substrate comprises at least one second metal interconnect, thereby electrically connecting the second metal interconnect to the third metal interconnect.

Optionally, the first substrate may comprise a base substrate having a front side and a backside opposite to the front side, wherein the first metal interconnect comprises a front-side metal interconnect layer formed on the front side of the base substrate and at least one through silicon via (TSV) that extends through the base substrate from the backside thereof and is connected to the front-side metal interconnect layer.

Optionally, forming the heat-equalizing layer on the surface of the first substrate may comprise:
forming a heat-dissipating material film on the surface of the first substrate at backside of the base substrate;
forming at least one through hole extending through the heat-dissipating material film and exposing the TSV; and
forming a metal interconnect block in each through hole, wherein the metal interconnect block is connected to the TSV and forms the third metal interconnect.

Optionally, at least one dummy hole extending through the heat-dissipating material film is formed at the same time as the through hole extending through the heat-dissipating material film and exposing the TSVs is formed, and wherein a heat-dissipating metal block is formed in the dummy hole at the same time as the metal interconnect block is formed in the through hole.

Optionally, forming the heat-equalizing layer on the surface of the first substrate may comprise:
forming a heat-dissipating material film on a third substrate;
forming at least one metal interconnect block extending through the heat-dissipating material film;
bonding a side of the first substrate where the TSV is formed to the third substrate so that the heat-dissipating material film faces the first substrate and that each metal interconnect block is connected to a corresponding TSV; and
removing the third substrate.

Optionally, forming the heat-equalizing layer on the surface of the first substrate may comprise:
forming a heat-dissipating material film on the third substrate;
forming at least one heat-dissipating groove extending parallel to the third substrate from an edge of the heat-dissipating material film into the heat-dissipating material film;
filling the heat-dissipating groove with a sacrificial layer;
forming at least one metal interconnect block extending through the heat-dissipating material film; removing the sacrificial layer;
bonding a side of the first substrate where the TSV is formed to the third substrate so that the heat-dissipating material film faces the first substrate and that each metal interconnect block is connected to a corresponding TSV; and
removing the third substrate.

In the semiconductor structure and method of the present invention, the heat-equalizing layer is arranged or formed between the stacked first and second substrates, and the heat-equalizing layer provided with the heat-dissipating material film can promote horizontal transfer of heat produced in the semiconductor structure between the first and second substrates, facilitating heat dissipation, mitigating heat concentration, expediting temperature equalization and avoiding local overheat, which may cause damage to devices in the semiconductor structure. The heat-equalizing layer does not occupy any portion of a horizontal area of the semiconductor structure. Therefore, it does not have any adverse impact on processes to be carried out on the first and second substrates, or on the design of devices therein, helping to increase stability and performance of the semiconductor structure.

### BRIEF DESCRIPTION OF THE DRAWINGS

FIG. 1 schematically illustrates a method for fabricating a semiconductor structure according to an embodiment of the present invention.

FIGS. 2a-2d depicts schematic cross-sectional views showing a method for fabricating a semiconductor structure according to a first embodiment of the present invention.

FIG. 3 shows a schematic plan view of an arrangement of heat-dissipating metal blocks according to an embodiment of the present invention.

FIGS. 4a-4f depicts schematic cross-sectional views showing a method for fabricating a semiconductor structure according to a second embodiment of the present invention.

FIGS. 5a-5e shows a schematic cross-sectional view of a heat-equalizing layer formed on a third substrate according to a third embodiment of the present invention.

FIGS. 6a-6e shows a schematic cross-sectional view of the heat-equalizing layer and a second substrate both stacked on a first substrate according to the third embodiment of the present invention.

### DETAILED DESCRIPTION

Semiconductor structures and methods according to specific embodiments of the present invention will be described in greater detail below with reference to the accompanying drawings. From the following description, advantages and features of the present invention will become more apparent. It will be understood that the figures are provided in a very simplified form not necessarily drawn to exact scale for the only purpose of helping to explain the embodiments disclosed herein in a more convenient and clearer way. Note that the order of steps in the method as presented herein is not the only order in which these steps must be performed. Rather, some of the steps may be omitted, and/or other steps that are not described herein may be added. It will be understood that, as used herein, spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations.

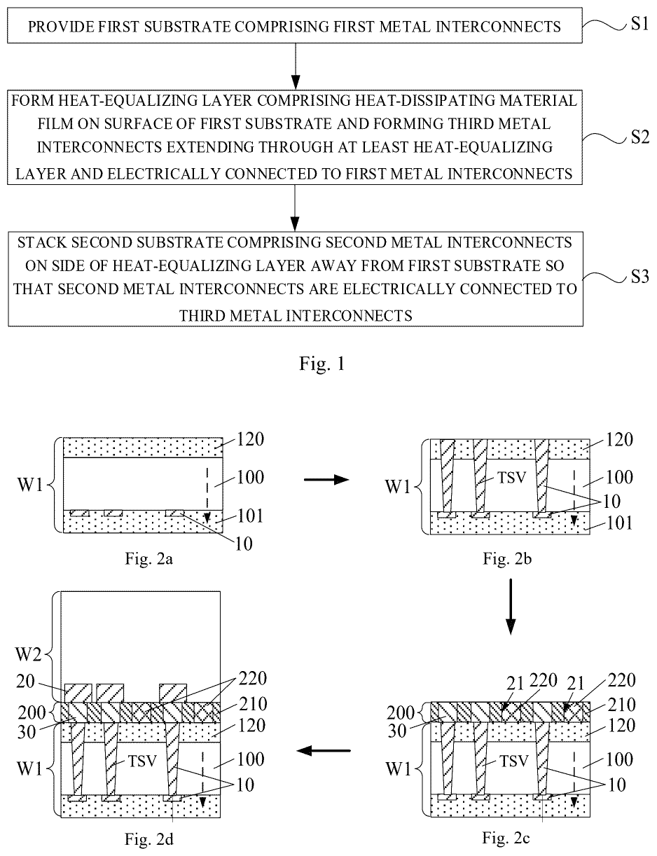

Referring to FIG. 1, a method for fabricating a semiconductor structure according to an embodiment of the present invention comprises the steps of:
S1: providing a first substrate comprising at least one first metal interconnect;
S2: forming a heat-equalizing layer on a surface of the first substrate, the heat-equalizing layer comprising a heat-dissipating material film and at least one third metal interconnect which extends through at least the heat-equalizing layer and is electrically connected to the first metal interconnects; and

S3: stacking, on a side of the heat-equalizing layer away from the first substrate, a second substrate comprising at least one second metal interconnect so that the second metal interconnect is electrically connected to the third metal interconnects.

In this method, the second substrate is stacked on one side of the first substrate, and the heat-equalizing layer is formed between the first and second substrates. The heat-equalizing layer provided with the heat-dissipating material film can promote horizontal transfer of heat produced in the semiconductor structure between the first and second substrates, facilitating heat dissipation, mitigating heat concentration, expediting temperature equalization and avoiding local overheat, which may cause damage to devices in the semiconductor structure. The heat-equalizing layer is sandwiched between the first and second substrates vertically (in a direction normal to the first substrate), without occupying any portion of a horizontal area of the semiconductor structure (which is an area of the semiconductor structure measured perpendicular to the normal of the first substrate). Therefore, it does not have any adverse impact on processes to be carried out on the first and second substrates, or on the design of devices therein, helping to increase stability and performance of the semiconductor structure.

Exemplary embodiments of the method of FIG. 1 are further described in Embodiment 1 to 3, and a semiconductor structure obtained according to the method is explained in Embodiment 4 below. It will be understood that these embodiments are presented only to more clearly illustrate the precepts of the present invention. Features described in connection with the individual embodiments are not to be construed as unique to the particular embodiments and may all be taken as features of a single combined embodiment. It will also be understood that those embodiments only represent specific manufacturing and application examples and are not intended to limit the scope of the present invention in any sense in terms of manufacturing and application.

### EMBODIMENT 1

A first embodiment is directed to a method for fabricating a semiconductor structure. Referring to FIG. 1 and FIG. 2a, in the method for fabricating a semiconductor structure of this embodiment, first of all, a first substrate W1 is provided, which comprises first metal interconnects 10.

The first substrate W1 is, for example, a silicon wafer or other semiconductor substrate. The first substrate W1 may have undergone a series of semiconductor processes, and one or more electronic components may have been formed therein. For example, the first substrate W1 may include a base substrate 100 (e.g., a silicon or other base substrate), and electronic components, dielectric materials and the like that are formed on the base substrate 100. The base substrate 100 may be a silicon (Si) base substrate, a germanium (Ge) base substrate, a SiGe base substrate, a silicon-on-insulator (SOI) base substrate, a germanium-on-insulator (GOI) base substrate, or the like. The electronic components may include at least one of MOS devices, sensing devices (e.g., light-sensing devices), memory devices (e.g., non-volatile or random access memory devices) and passive devices (e.g., resistors, capacitors, etc.) The base substrate 100 has a front side (as indicated by the arrows) and a backside opposite to the front side. The electronic components may be formed, for example, on the front side of the base substrate 10. For example, logic circuits are formed in the first substrate W1.

The first substrate W1 may be a single substrate, or a stack of two or more substrates. Depending on the composition of the first substrate W1, the first metal interconnect 10 may include at least one of: a metal interconnect layer formed on the front side of the backing substrate 100 (as indicated by the dashed arrows of FIG. 2a) (referred to hereinafter as the “front-side metal interconnect layer”); through silicon via (TSV) formed in the backing substrate 100; and a metal interconnect layer formed on the backside of the base substrate 100 (“backside metal interconnect layer”). In FIG. 2a, a portion of the front-side metal interconnect layer in the first metal interconnects 10 are shown. The front-side metal interconnect layer is isolated by a dielectric material 101.

In the present embodiment, a heat-equalizing layer and a second substrate are subsequently stacked on the backside of the base substrate 100. In order to facilitate connection of the first metal interconnect 10 with the second substrate, as shown in FIG. 2a-2d, after necessary processes are completed on the front side of the base substrate 100, the base substrate 100 is thinned from the backside, and a backside dielectric layer 120 (e.g., silicon oxide) is formed on a surface of the thinned base substrate 100. A TSV process is then performed on the backside of the base substrate 100, forming TSVs (labeled as “TSV” in FIG. 2b) extending through the base substrate 100 and connected to front-side metal interconnect layer. That is, the first metal interconnect 10 include the TSV. However, the present invention is not so limited. In an alternative embodiment, if required, the stacking heat-equalizing layer and the second substrate may be subsequently stacked on the front side of the base substrate 100 in the first substrate W1, and the second substrate may be connected to front-side metal interconnect layer in the first metal interconnects 10. In this case, before the heat-equalizing layer and the second substrate are stacked, the base substrate 100 may not be thinned, and TSV may not be formed.

Subsequently, as shown in FIG. 2c, on one side of the first substrate W1 are formed a heat-equalizing layer 200 and third metal interconnects 30 extending through at least the heat-equalizing layer 200 and electrically connected to the first metal interconnects 10.

The heat-equalizing layer 200 includes a heat-dissipating material film 210 capable of speeding up heat equalization. The heat-dissipating material film 210 may be formed of various materials with good thermal conductivity. For example, the heat-dissipating material film 210 may include one of diamond, hexagonal boron nitride (h-BN) and carbon nanotubes, or a combination of two or more thereof. The heat-equalizing layer 200 may further include one or more films formed over or under the heat-dissipating material film 210. As an example only, as shown in FIG. 2c, the heat-equalizing layer 200 may consist of a single layer and may be formed including: forming the heat-dissipating material film 210 on the backside of the base substrate 100 in the first substrate W1; then forming through holes in the heat-dissipating material film 210, which expose TSVs in the first substrate W1; and afterwards, forming, in the through holes, metal interconnect blocks connected to the TSVs. The metal interconnect block forms the aforementioned third metal interconnect 30 that is connected to the first metal interconnect 10.

In addition to heat equalization provided by the heat-dissipating material film 210, in order to facilitate heat dissipation, additionally mitigate local heat concentration, avoid local overheat and improve heat equalization, as shown in FIG. 2c, dummy holes 21 extending through the heat-dissipating material film 210 may be formed at the same time as the through holes extending through the heat-dissipating material film 210 and exposing the TSVs are formed in the heat-dissipating material film 210, and heat-dissipating metal blocks 220 are formed in the dummy holes 21 at the same time as the metal interconnect blocks are formed in the through holes. The dummy hole 21 may be formed away from the through hole, and the number, locations and size of them may be properly determined as required by the desired heat dissipation performance. FIG. 3 shows an exemplary arrangement of the dummy holes 21 in the heat-dissipating material film 210 according to an embodiment. As shown in FIG. 3, the dummy hole 21 may have a square, rectangular or other cross-section.

In the present embodiment, the third metal interconnect 30 is formed by the metal interconnect block that extends through the heat-equalizing layer 200 and is connected to the TSV in the first metal interconnect 10. However, the present invention is not so limited. In an alternative embodiment, after the base substrate 100 is thinned and before the heat-equalizing layer 200 is formed on the backside of the base substrate 100, instead of forming TSVs connected to the front-side metal interconnect layer in the first substrate W1, after the heat-equalizing layer 200 is formed on the backside of the base substrate 100, a TSV process is performed on the backside of the base substrate 100 to form TSVs which extend through heat-dissipating material film 210 and the base substrate 100 and are connected to the front-side metal interconnect layer. The TSV is to be subsequently interconnected with the second substrate. In this case, the TSV extending through the heat-equalizing layer 200 and the base substrate 100 and connected to the front-side metal interconnect layer forms the third metal interconnect.

In one exemplary embodiment, heat-dissipating grooves (not shown in FIGS. 2a-2d) may be further formed in the heat-equalizing layer 200, which extend parallel to the first substrate W1 (i.e., perpendicular to the normal of the first substrate W1) from an edge of the heat-equalizing layer 200 into the heat-equalizing layer 200. The heat-dissipating groove may act as a heat-dissipating channel, and a cooling fluid may be introduced therein to expedite heat dissipation from the heat-equalizing layer 200.

After that, as shown in FIG. 2d, the second substrate W2 is stacked on the side of the heat-equalizing layer 200 away from the first substrate W1. The second substrate W2 comprises second metal interconnects 20 and may consist either of a single substrate, or of a stack of two or more substrates. The second substrate W2 may include a semiconductor base substrate and electronic components, dielectric materials and the like formed on the semiconductor base substrate. The electronic components may include at least one of MOS devices, sensing devices, memory devices and passive devices. For example, the second substrate W2 may contain multilayer memory devices. Depending on the composition of the second substrate W2, the second metal interconnect 20 may include at least one of: metal interconnect layer formed in the dielectric material of the second substrate W2; and TSV extending through the semiconductor base substrate of the second substrate W2. FIG. 2d shows, as an example, metal interconnect layer of the second metal interconnect 20 which is intended to be bonded and connected to the third metal interconnect 30.

As a result of the bonding, the second metal interconnect 20 in the second substrate W2 is electrically connected to the aforementioned third metal interconnect 30, interconnecting the first substrate W1 and the second substrate W2. In some embodiments, in order to achieve higher bonding strength and facilitate heat dissipation, dummy bond pads (not shown) may be formed on a surface of the second substrate W2 and bonded to the heat-dissipating metal blocks 220 in the heat-equalizing layer 200.

### EMBODIMENT 2

A method for fabricating a semiconductor structure according to a second embodiment is substantially similar to that of FIG. 1, except that, in step S2, instead of forming the heat-equalizing layer 200 directly over the first substrate W1 as a backing support as with the first embodiment, in the second embodiment, the heat-equalizing layer is formed over a third substrate, as a backing support, which is different from the first substrate W1. Moreover, the third substrate is bonded to the first substrate W1 so that the heat-equalizing layer is retained on a surface of the first substrate W1. In this way, the first substrate W1 can be avoided from being affected by heat generated during the formation of the heat-equalizing layer, improving reliability of the resulting semiconductor structure.

It should be noted that the following description highlights the differences of the second embodiment from the first embodiment, and some films and processes involved in the method, which are common to the first embodiment, are not repeated. Reference can be made to the above description in connection with the first embodiment for details of such films and processes.

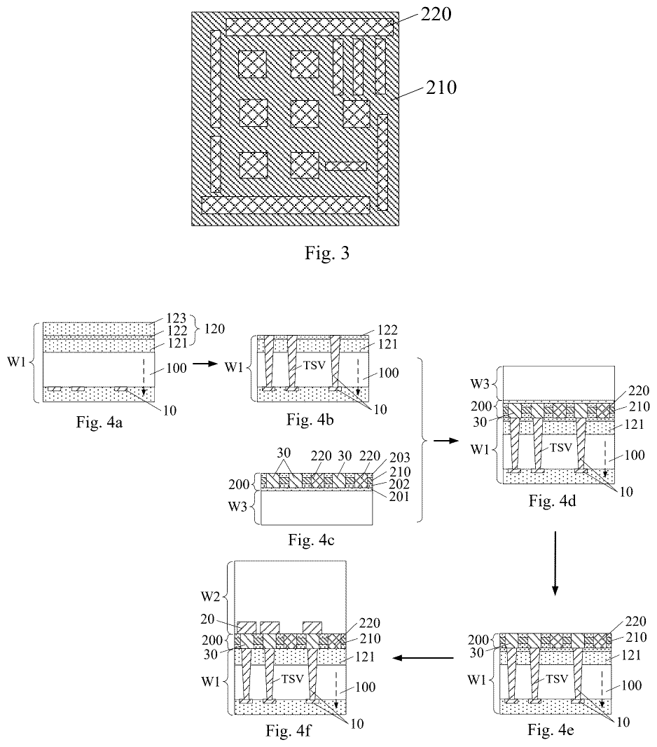

Referring to FIG. 1 and of FIG. 4a, in the method for fabricating a semiconductor structure of this embodiment, first of all, a first substrate W1 is provided which includes a base substrate 100 and dielectric materials formed on front (as indicated by the dashed arrows of FIG. 4a) and back sides of the base substrate 100. For example, backside dielectric layer 120 including a first backside oxide layer 121, a backside nitride layer 122 and a second backside oxide layer 123 may be successively stacked on the backside of the backing substrate 100 after the base substrate 100 is thinned. The first and second backside oxide layers 121, 123 may, for example, each include silicon oxide, and the backside nitride layer 122 may, for example, include silicon nitride or silicon carbonitride (SiCN). First metal interconnects 10 include front-side metal interconnect layer formed on the front side of the base substrate 100. In order to connect the first metal interconnects 10 at the backside of the base substrate 100 to a second substrate, as shown in FIG. 4b, TSVs (labeled as “TSV” in the figure) are formed from the backside of the base substrate 100 and extend through the base substrate 100 and are connected to the front-side metal interconnect layer. The first metal interconnect 10 also includes the TSV. The formation of the TSVs may involve removing a metal material outside respective holes using a chemical mechanical polishing (CMP) process and removing the second backside oxide layer 123 after the CMP process is completed.

As shown in FIG. 4c, a heat-equalizing layer 200 is formed over a third substrate W3, which may be, for example, a passive substrate. The formation of the heat-equalizing layer 200 over the third substrate W3 may, for example, include the processes as follows.

At first, a heat-dissipating material film 210 is formed over the third substrate W3. The heat-dissipating material film 210 may be formed of various materials with good thermal conductivity. Optionally, a pad oxide film 201 and a first nitride film 202 may also be formed between the heat-dissipating material film 210 and the third substrate W3, and a second nitride film 203 formed on the side of the heat-dissipating material film 210 away from the third substrate W3. The pad oxide film 201 may include silicon oxide, and the first nitride film 202 and the second nitride film 203 may each include silicon nitride or silicon carbonitride (SiCN).

After that, through holes extending through the second nitride film 203 and the heat-dissipating material film 210 are formed. In the present embodiment, the through holes may, for example, further extend through at least a partial thickness of the first nitride film 202. Optionally, dummy holes may also be formed, which extend through the second nitride film 203, the heat-dissipating material film 210 and, optionally, at least a partial thickness of the first nitride film 202.

Subsequently, metal interconnect blocks are formed in the through holes, and simultaneously heat-dissipating metal blocks 220 are formed in the dummy holes. The metal interconnect blocks and the heat-dissipating metal blocks 220 are embedded in the stack of the first nitride film 202, the heat-dissipating material film 210 and the second nitride film 203. For example, the heat-equalizing layer 200 may include the aforementioned first nitride film 202, heat-dissipating material film 210, second nitride film 203 and heat-dissipating metal blocks 220. In the present embodiment, the metal interconnect block formed in the through hole forms third metal interconnect 30. The metal interconnect block may be single unitary piece, but the present invention is not so limited, as in some alternative embodiments, the third metal interconnect 30 extending through the heat-equalizing layer 200 may include two or more separate metal components. Such metal components may include metal block, metal via, metal layer, etc.

As with the first embodiment, the third metal interconnect 30 is formed to connect the first metal interconnect 10. In addition to heat equalization provided by the heat-dissipating material film 210, the heat-dissipating metal block 220 can facilitate heat dissipation, additionally mitigate local heat concentration, avoid local overheat, which may cause damage to devices in the semiconductor structure, and improve heat equalization. Optionally, heat-dissipating grooves may be further formed in the heat-equalizing layer 200, which extend parallel to the third substrate W3 (i.e., perpendicular to a normal of the third substrate W3) from edges of the heat-equalizing layer 200 into the heat-equalizing layer 200. The heat-dissipating grooves may act as heat-dissipating channels, and a cooling fluid may be introduced therein to expedite heat dissipation from the heat-equalizing layer 200.

As shown in FIG. 4d, the first substrate W1 is then bonded at the side with the TSV to the third substrate W3 so that the heat-dissipating material film 210 is adjacent to the first substrate W1. As a result of the bonding, the third metal interconnect 30 (i.e., the metal interconnect blocks in this embodiment) is connected to TSV in the first substrate W1.

Next, the third substrate W3 is removed by polishing and/or etching, with the heat-equalizing layer 200 being retained on a surface of the first substrate W1. As shown in FIG. 4e, as a result of the removal of the third substrate W3, the third metal interconnect 30 (i.e., the metal interconnect block in this embodiment) and the heat-dissipating metal block 220 in the heat-equalizing layer 200 are exposed on the backside of the base substrate 100.

Afterwards, as shown in FIG. 4f, a second substrate W2 comprising second metal interconnects 20 is stacked on and bonded to the side of the heat-equalizing layer 200 away from the first substrate W1 so that the second metal interconnects 20 in the second substrate W2 are electrically connected to the aforementioned third metal interconnects 30, thereby interconnecting the first substrate W1 and the second substrate W2.

### EMBODIMENT 3

A third embodiment relates to a method for fabricating a semiconductor structure. As with the second embodiment, in the third embodiment, the heat-equalizing layer is formed over the third substrate that is different from the first substrate W1 as a backing support, and the third substrate is then bonded to the first substrate W1 so that the heat-equalizing layer is retained on a surface of the first substrate W1. The third embodiment differs from the first and second embodiments essentially in that, in the third embodiment, during the formation of the heat-equalizing layer, heat-dissipating grooves are formed, which extend parallel to the third substrate (i.e., perpendicular to the normal of the third substrate W3) from edges of the heat-equalizing layer into the heat-equalizing layer. It should be noted that the following description highlights the differences of the third embodiment from the first and second embodiments, and some films and processes involved in the method, which are common to the first and/or second embodiments, are not repeated. Reference can be made to the above description in connection with the first and/or second embodiments for details of such films and processes.

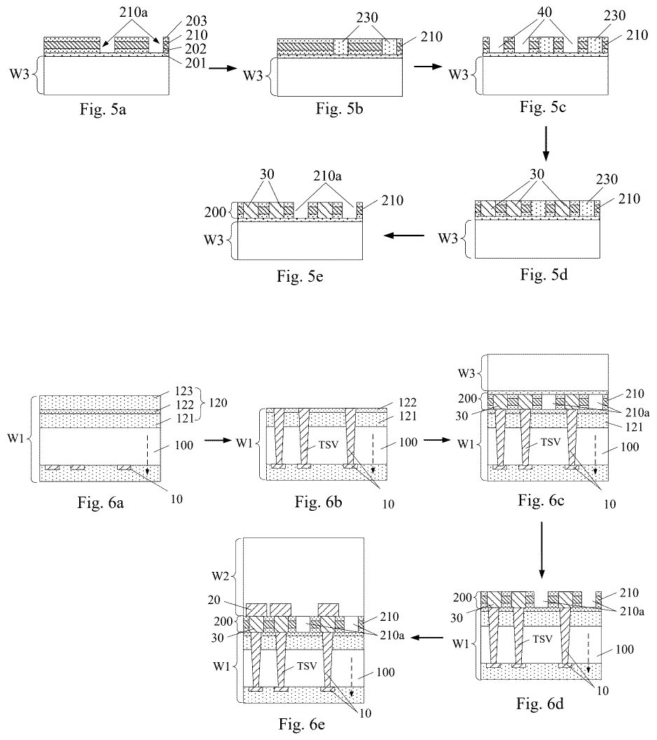

Referring to FIGS. 5a-5e, a heat-equalizing layer 200 is formed on a third substrate W3, and the formation may, for example, include the processes as follows.

First of all, as shown in FIG. 5a, the third substrate W3 is provided, which is, for example, a passive substrate, and a heat-dissipating material film 210 is formed over the third substrate W3. Optionally, a pad oxide film 201 and a first nitride film 202 may also be formed between the heat-dissipating material film 210 and the third substrate W3, and a second nitride film 203 may be formed on the side of the heat-dissipating material film 210 away from the third substrate W3. The pad oxide film 201 may include silicon oxide, and the first nitride film 202 and the second nitride film 203 may each include silicon nitride or silicon carbonitride (SiCN). In addition, heat-dissipating grooves 210a are formed, which extend parallel to the third substrate W3 from edges of the heat-dissipating material film 210 into the heat-dissipating material film 210. The heat-dissipating grooves 210a extend through the second nitride film 203, the heat-dissipating material film 210 and, optionally, at least a partial thickness of the first nitride film 202.

Next, as shown in FIG. 5b, a sacrificial layer 230 is filled in the heat-dissipating grooves 210a, in order to provide protection to the heat-dissipating grooves 210a during the subsequent formation of through holes in the stack of the first nitride film 202, the heat-dissipating material film 210 and the second nitride film 203. The sacrificial layer 230 may be silicon oxide, silicon, a bottom anti-reflective coating (BARC) or any other suitable material.

Subsequently, as shown in of FIG. 5c, through holes 40 extending through the second nitride film 203 and the heat-dissipating material film 210 are formed. Simultaneously, dummy holes (not shown) extending through the second nitride film 203 and the heat-dissipating material film 210 in the stack may also be formed. The through hole 40 and the dummy hole may also extend through at least a partial thickness of the first nitride film 202.

After that, as shown in FIG. 5d, metal interconnect blocks are formed in the through holes 40, which are to be subsequently connected to first metal interconnects 10 in a first substrate W1. If the dummy holes are formed, heat-dissipating metal blocks may be formed in the dummy holes at the same time as the metal interconnect blocks are formed in the through holes (see Embodiments 1 and 2 above). For example, the metal interconnect block and the heat-dissipating metal block may extend through the first nitride film 202, the heat-dissipating material film 210 and the second nitride film 203 and thereby be embedded in the stack. In the present embodiment, the metal interconnect block formed in the through hole 40 forms the third metal interconnect 30 and is a single unitary piece. However, the present invention is not so limited. For example, in some alternative embodiments, the third metal interconnect 30 extending through the heat-equalizing layer 200 may include two or more separate metal components.

Afterwards, as shown in FIG. 5e, the sacrificial layer 230 is removed from the heat-dissipating grooves 210a. Thus, the heat-equalizing layer 200 includes the aforementioned stack of the first nitride film 202, the heat-dissipating material film 210 and the second nitride film 203 and the heat-dissipating metal blocks 220 embedded in the stack, and the heat-dissipating grooves 210a have been formed in the heat-equalizing layer 200. In some alternative embodiments, the sacrificial layer 230 may not be removed at this point. Instead, after the third substrate W3 is subsequently bonded to a first substrate W1, or after a second substrate W2 is subsequently bonded to one side of the first substrate W1, since the heat-dissipating groove 210a extends to the edge of the heat-equalizing layer 200, the sacrificial layer 230 will be exposed on side face of the bonded substrates. The sacrificial layer 230 may be then removed using a wet or dry etching process.

After the heat-equalizing layer 200 is formed over the third substrate W3, the third substrate W3 is bonded to a first substrate W1.

As shown in FIG. 6a, a first substrate W1 is provided, which includes a base substrate 100 and dielectric materials formed on front (as indicated by the dashed arrows of FIG. 6a) and back sides of the base substrate 100. For example, backside dielectric layer 120 including a first backside oxide layer 121, a backside nitride layer 122 and a second backside oxide layer 123 may be successively stacked on the backside of the base substrate 100 after the backing substrate 100 is thinned. First metal interconnect 10 include front-side metal interconnect layer formed on the front side of the base substrate 100. In order to connect the first metal interconnects 10 at the backside of the base substrate 100 to a second substrate, as shown in FIG. 6b, TSVs (labeled as “TSV” in the figure) are formed from the backside of the base substrate 100 and extend through the base substrate 100 and are connected to the front-side metal interconnect layer. The first metal interconnect 10 also includes the TSV.

Subsequently, as shown in FIG. 6c, the first substrate W1 is then bonded at the side with the TSVs to the third substrate W3 so that the heat-dissipating material film 210 is adjacent to the first substrate W1. As a result of the bonding, the third metal interconnect 30 (i.e., the metal interconnect blocks in this embodiment) is connected to TSV in the first substrate W1.

Next, as shown in FIG. 6d, the third substrate W3 is removed by polishing and/or etching, with the heat-equalizing layer 200 being retained on a surface of the first substrate W1. In the present embodiment, as a result of the removal of the third substrate W3 by polishing and/or etching, the third metal interconnect 30 and the heat-dissipating groove 210a in the heat-equalizing layer 200 are exposed on the backside of the backing substrate 100.

Afterwards, as shown in FIG. 6e, a second substrate W2 comprising second metal interconnects 20 may be stacked on and bonded to the side of the heat-equalizing layer 200 away from the first substrate W1 so that the second metal interconnect 20 in the second substrate W2 are electrically connected to the aforementioned third metal interconnect 30, thereby interconnecting the first substrate W1 and the second substrate W2.

### EMBODIMENT 4

A fourth embodiment of the present invention relates to a semiconductor structure obtainable according to the method for fabricating a semiconductor structure of FIG. 1.

Referring to FIGS. 2a-2d to FIGS. 6a-6e, the semiconductor structure of this embodiment includes:
a first substrate W1 comprising first metal interconnects 10;
a second substrate W2 stacked on the first substrate W1 and comprising second metal interconnects 20;
a heat-equalizing layer 200 sandwiched between the first substrate W1 and the second substrate W2 and including a heat-dissipating material film 210; and
third metal interconnects 30 extending through at least the heat-equalizing layer 200 and electrically connecting the first metal interconnect 10 to the second metal interconnect 20.

For example, the heat-dissipating material film 210 may include one of diamond, hexagonal boron nitride (h-BN) and carbon nanotubes, or a combination of two or more thereof.

Referring to FIGS. 2a-2d to FIGS. 4a-4f, in some embodiments, the heat-equalizing layer 200 may include heat-dissipating metal blocks 220 extending through the heat-dissipating material film 210.

Referring to FIGS. 6a-e, in some embodiments, heat-dissipating grooves 210a may be formed in the heat-equalizing layer 200, which extend parallel to the first substrate W1 from edge of the heat-equalizing layer 200 into the heat-equalizing layer 200.

The third metal interconnect 30 extends through the heat-equalizing layer 200 and is connected to the first metal interconnect 10 and the second metal interconnect 20. The third metal interconnect 30 may include metal interconnect block which is disposed between the first metal interconnect 10 and the second metal interconnect 20 and connects the first metal interconnect 10 to the second metal interconnect 20. Alternatively, the third metal interconnect 30 may include at least one interconnect metal layer any metal via disposed between the first metal interconnect 10 and the second metal interconnect 20. The metal via may connect different interconnect metal layers, and/or connect interconnect metal layer to the first metal interconnect 10, and/or connect interconnect metal layer to the second metal interconnect 20.

For example, in some embodiments, as shown in FIGS. 2a-2d, FIGS. 4a-4f, FIGS. 5a-5e and FIGS. 6a-6e, the first substrate W1 includes a base substrate 100 having a front side (e.g., as indicated by the dashed arrows) and a backside opposite to the front side. The first metal interconnect 10 includes front-side metal interconnect layer formed on the front side of the base substrate 100 and TSV extending through the base substrate 100 from the backside thereof and connected to the front-side metal interconnect layer. The third metal interconnect 30 includes metal interconnect block extending through the heat-equalizing layer 200 and connected to the TSV. However, the present invention is not so limited. For example, in one embodiment, the heat-equalizing layer 200 and the second substrate W2 are stacked on the front side of the base substrate 100 in the first substrate W1. In this case, the first metal interconnect 10 may include the front-side metal interconnect layer formed on the front side of the base substrate 100, but not the TSV. In an alternative embodiment, the heat-equalizing layer 200 and the second substrate W2 are stacked on the backside of the base substrate 100 in the first substrate W1. In this case, after the heat-equalizing layer 200 is stacked, the TSV may be formed from the backside of the base substrate 100, the TSV extends through the heat-equalizing layer 200 and the base substrate 100 and connected to the front-side metal interconnect layer on the front side of the base substrate 100 in the first substrate W1, and the TSV may be interconnected at the backside of the base substrate 100 with the second substrate W2. The TSV may provide the third metal interconnect 30.

In addition to the first substrate W1 and the second substrate W2, the semiconductor structure may further include one or more other substrates stacked in a direction perpendicular to the substrates. Depending on the desired heat dissipation performance, heat-equalizing layer(s) may be arranged between adjacent substrates in a similar manner for arranging the heat-equalizing layer 200 between the first substrate W1 and the second substrate W2.

In the semiconductor structure of this embodiment, the heat-equalizing layer 200 formed between the first substrate W1 and the second substrate W2 can promote horizontal transfer of heat produced in the semiconductor structure between the first substrate W1 and the second substrate W2, facilitating heat dissipation, mitigating heat concentration, expediting temperature equalization and avoiding local overheat, which may cause damage to devices in the semiconductor structure. The heat-equalizing layer 200 is vertically sandwiched between the first substrate W1 and the second substrate W2, without occupying any portion of a horizontal area of the semiconductor structure. Therefore, it does not have any adverse impact on processes to be carried out on the first substrate W1 and the second substrate W2, or on the design of devices therein, helping to increase stability and performance of the semiconductor structure.

It is noted that the embodiments disclosed herein are described in a progressive manner, with the description of each embodiment focusing on its differences from others. Cross-reference can be made between the embodiments for their common or similar features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

What is claimed is:

1. A semiconductor structure, comprising:
a first substrate comprising at least one first metal interconnect;
a second substrate stacked on the first substrate and comprising at least one second metal interconnect;
a heat-equalizing layer that is sandwiched between the first and second substrates and comprises a heat-dissipating material film; and
at least one third metal interconnect extending through at least the heat-equalizing layer and electrically connecting the first metal interconnect to the second metal interconnect.

2. The semiconductor structure of claim 1, wherein the heat-dissipating material film comprises one of diamond, hexagonal boron nitride (h-BN) and carbon nanotubes, or a combination of at least two thereof.

3. The semiconductor structure of claim 1, wherein the heat-equalizing layer comprises at least one heat-dissipating metal block that extends through the heat-dissipating material film.

4. The semiconductor structure of claim 1, wherein the heat-equalizing layer comprises at least one heat-dissipating groove, wherein the heat-dissipating groove extends parallel to the first substrate from an edge of the heat-equalizing layer into the heat-equalizing layer.

5. The semiconductor structure of claim 1, wherein the first substrate comprises a base substrate having a front side and a backside opposite to the front side, wherein the first metal interconnect comprises a front-side metal interconnect layer formed on the front side of the base substrate and at least one through silicon via (TSV) extending through the base substrate from the backside thereof and connected to the front-side metal interconnect layer, and wherein the third metal interconnect comprises a metal interconnect block that extends through the heat-equalizing layer and is connected to the TSV.

6. The semiconductor structure of claim 1, wherein the first substrate comprises a base substrate having a front side and a backside opposite to the front side, wherein the first metal interconnect comprises a front-side metal interconnect layer formed on the front side of the base substrate, and wherein the third metal interconnect comprises at least one TSV that extends through the heat-equalizing layer and the base substrate and is connected to the front-side metal interconnect layer.

7. A method for fabricating a semiconductor structure, comprising:
providing a first substrate comprising at least one first metal interconnect;
forming a heat-equalizing layer that comprises a heat-dissipating material film on a surface of the first substrate;
forming at least one third metal interconnect extending through at least the heat-equalizing layer and electrically connected to the first metal interconnect; and
stacking a second substrate on a side of the heat-equalizing layer away from the first substrate, wherein the second substrate comprises at least one second metal interconnect, thereby electrically connecting the second metal interconnect to the third metal interconnect.

8. The method of claim 7, wherein the first substrate comprises a base substrate having a front side and a backside opposite to the front side, wherein the first metal interconnect comprises a front-side metal interconnect layer formed on the front side of the base substrate and at least one through silicon via (TSV) that extends through the base substrate from the backside thereof and is connected to the front-side metal interconnect layer.

9. The method of claim 8, wherein forming the heat-equalizing layer on the surface of the first substrate comprises:
forming a heat-dissipating material film on the surface of the first substrate at the backside of the base substrate;
forming at least one through hole extending through the heat-dissipating material film and exposing the TSV; and
forming a metal interconnect block in each through hole, wherein the metal interconnect block is connected to the TSV and forms the third metal interconnect.

10. The method of claim 9, wherein at least one dummy hole extending through the heat-dissipating material film is formed at the same time as the through hole extending through the heat-dissipating material film and exposing the TSVs is formed, and wherein a heat-dissipating metal block is formed in the dummy hole at the same time as the metal interconnect block is formed in the through hole.

11. The method of claim 8, wherein forming the heat-equalizing layer on the surface of the first substrate comprises:
forming a heat-dissipating material film on a third substrate;
forming at least one metal interconnect block extending through the heat-dissipating material film;
bonding a side of the first substrate where the TSV is formed to the third substrate so that the heat-dissipating material film faces the first substrate and that each metal interconnect block is connected to a corresponding TSV; and
removing the third substrate.

12. The method of claim 8, wherein forming the heat-equalizing layer on the surface of the first substrate comprises:
forming a heat-dissipating material film on the third substrate;
forming at least one heat-dissipating groove extending parallel to the third substrate from an edge of the heat-dissipating material film into the heat-dissipating material film;
filling the heat-dissipating groove with a sacrificial layer;
forming at least one metal interconnect block extending through the heat-dissipating material film;
removing the sacrificial layer;
bonding a side of the first substrate where the TSV is formed to the third substrate so that the heat-dissipating material film faces the first substrate and that each metal interconnect block is connected to a corresponding TSV; and
removing the third substrate.
